(19) United States
(12) Patent Application Publication
(10) Pub. No.: US 2008/0198740 A1
(43) Pub. Date: Aug. 21, 2008

(54) Service take-over system of multi-host system and method therefor

(75) Inventors: Hong-Liang Liu, Tianjin (CN); Tom Chen, Taipei (TW); Win-Harn Liu, Taipei (TW)

Correspondence Address: RABIN & Berdo, PC, 1101 14TH STREET, NW, SUITE 500, WASHINGTON, DC, 20005, US

(73) Assignee: INVENTEC CORPORATION

(21) Appl. No.: 11/707,874

(22) Filed: Feb. 20, 2007

(51) Int. Cl. G01R 31/08

(52) U.S. Cl. 370/221

(57) ABSTRACT

A service take-over system of a multi-host system and a method therefor are provided, in which the multi-host system includes a service host and at least one standby host with their operating state monitored mutually via a heartbeat mechanism. When the service host for providing a service externally fails, an external public IP address for providing a service externally of the service host is taken over to a standby host. A service environment required for taking over the service of the service host to the standby host is prepared. The preparation state of the service environment is detected, and access request data packets via the external public IP address to the service are dropped before the service environment gets ready. The service is taken over after the service environment is ready, and the access request data packets to the service are received, so as to provide the service externally.

### BACKGROUND OF THE INVENTION

1. Field of Invention

The present invention relates to a service take-over technique of a multi-host system or a cluster system, and more particularly to a service take-over system of a high available cluster system and a method therefor.

2. Related Art

Currently, to make a computer system that operates an important task provides an uninterrupted service, the most common way is arranging a high available cluster or a multi-host system. The high available cluster is usually constituted by at least two hosts, in which during the process of externally providing a service, one host provides a normal service, and other hosts are in a “standby” state. Moreover, the hosts mutually monitor the operating states thereof via a “Heartbeat” mechanism.

For example, FIG. 1 is a schematic view of a typical high available cluster structure. In the exemplary embodiment, the whole system, i.e., a host system 10 is constituted by two hosts, a host 12 and a host 14, respectively having a private internet protocol (private IP) address of 192.168.0.1 and 192.168.0.2. However, the host system 10 provides a service externally via an accessible public internet protocol address, i.e., a public IP address 10.10.1.10. A client accesses the host system 10 via the public IP address. Seen from the viewpoint of the client, the whole system is a host system for providing a public IP address 10.10.1.10, so the whole system hides the specific structure from the client. The two hosts 12, 14 mutually detect the state via the “heartbeat” mechanism. When the “standby” host detects that the current host for providing a service fails and can not provide any service or is in an unstable operating state, the “standby” host takes over the public IP address and the work of the failed host, so as to provide the service externally. Meanwhile, the failed host begins to recover from the error, and when recovering to the normal state, the host is in a “standby” state, preparing to take over the service of the failed host at any time.

At present, nearly all the services provided by the cluster can be fulfilled through a network, and only by being provided through a network, the services can be switched uninterruptedly between multiple hosts of the cluster system. However, the properties of the services provided externally via the public IP address are different, and thus whether the service is available after the public IP address is taken over varies. For example, some services can be provided immediately after the public IP address is taken over, such as internet-only services of dynamic host configuration protocol (DHCP), domain name service (DNS), Telnet, and HTTP service for static webpage website browsing, in which the services can be activated as long as there is a small configuration file the same as that of the failed host, and thus can be uninterruptedly provided externally.

On the contrary, file services such as file transfer protocol (FTP), HTTP are not available at once, as these services not only provide a network connection, but also provide a file storage space. The file storage space needs a preparation time, and it should be ensured that the file storage space of the host for providing a service at present is at the same position as that of the host for providing a service previously. Further, if the access service to a block device is provided via a network, for example, an internet small computer system interface (iSCSI), the situation becomes more complicated, as the host not only has to provide an external connection service, but also has to ensure that the disk is the same before and after the failure switch and the physically accessed disk cannot be altered during the switch. Under such circumstance, the service cannot be taken over immediately, but should wait till the disk system gets ready.

Therefore, after the operating host takes over the public IP in time, if the software/hardware environment preparation is inadequate before the take-over, and especially when the network service is taken over in security after a long time of hardware preparation, (for example, for the iSCSI service, it must be ensured that the arrangement of the hard disk and the corresponding redundant array of inexpensive disks (RAID), logical volume (LV) are ready before the public IP address and the network service itself are taken over, which at least takes 30 seconds as the hardware preparation usually requires for a long time), if the service is accessed via the public IP address before the hardware gets ready, “Denial of Service” may occur and thus an access denied error appears. The system then provides an error reporting service, so the conventional art cannot achieve an uninterrupted and transparent service take-over.

### SUMMARY OF THE INVENTION

To solve the problems and defects in the conventional art, the present invention is directed to provide a service take-over system of a multi-host system and a method therefor, such that when a host for providing a service in the multi-host system fails, other operating hosts can safely, uninterruptedly, and transparently take over the public IP address and the service of the failed host, so as to ensure the operation and the function of the service in a normal state.

To achieve the above object, a service take-over system is disclosed, which is applicable to a multi-host system including a service host and at least one standby host. The service host provides a service externally via an external public IP address, and the standby host is in a standby state. The service host and the at least one standby host mutually monitor the operating states thereof via a heartbeat mechanism. The service take-over system includes a public IP address take-over module, a service take-over module, and a request processing module. The public IP address take-over module is used to determine the operating state of the service host via the heartbeat mechanism, and send a resource release request to inform the service host to release the occupied external public IP address and the service when the service host fails, so as to take over the external public IP address of the service host to one of the standby hosts. The service take-over module is used to prepare a service environment required for taking over the service of the service host to the standby host, and take over the service. The request processing module is used to detect the preparation state of the service environment of the service take-over module, and drop access request data packets via the external public IP address to the service before the service environment gets ready.

Moreover, a service take-over method is disclosed, which is applicable to a multi-host system including a service host and at least one standby host. The service host and the at least one standby host mutually monitor the operating states thereof via a heartbeat mechanism. The method includes: determining the operating state of the service host via the heartbeat mechanism, and sending a resource release request to inform the service host to release the occupied external public IP address and service when the service host fails; taking over an external public IP address for providing a service externally of the service host to one of the standby hosts; preparing a service environment required for taking over the service of the service host to the standby host; detecting the preparation state of the service environment, and dropping the access request data packets via the external public IP address to the service before the service environment gets ready; and taking over the service after the service environment is ready, and receiving the access request data packets to the service, so as to provide the service externally.

When the present invention provides a high available service via the public IP address and service take-over in a multi-host system and a similar environment, for a service take-over requiring for preparation time, to ensure the service of the failed host is available externally after the public IP address is taken over, the service environment required for taking over the service is prepared before the service take-over and the request data packets accessing the service are dropped before the service environment is ready. Further, the preparation state of the service environment is detected constantly till the preparation is finished, thus taking over the service and providing the service externally.

Therefore, the present invention has the following advantages. The service characterized in being rapidly taken over can be provided at once, and it is ensured that the connection between the client and the service host is maintained when the service cannot be provided immediately, thereby achieving an uninterrupted and transparent take-over of the public IP address and service in the multi-host system.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and thus is not limitative of the present invention, and wherein:

FIG. 1 is a schematic view of the structure of a typical high available double-host cluster system;

FIG. 2 is the multi-host service take-over system according to the present invention;

FIG. 3 is a flow chart of the processes of the multi-host service take-over method according to the present invention;

FIG. 4 is a flow chart of the access request processing of the service in a “Protected” state; and

FIG. 5 is a flow chart of the access request processing of the service in a “Ready” state.

### DETAILED DESCRIPTION OF THE INVENTION

The features and practice of the preferred embodiments of the present invention will be illustrated in detail below with the accompanying drawings.

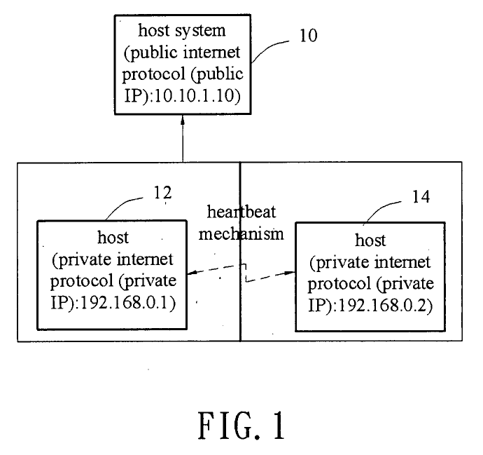

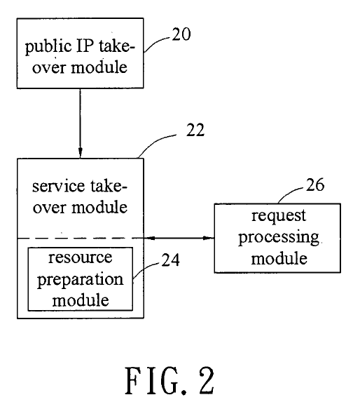

Referring to FIG. 2, a multi-host service take-over system according to the present invention is shown. The multi-host system includes a service host and at least one standby host. For example, in the embodiment of FIG. 1, the multi-host system 10 includes a host 12 and a host 14. It is assumed that the host 12 is a service host, the host 14 is a standby host, and the service host 12 and the standby host 14 mutually monitor the operating states thereof via a heartbeat mechanism. Thus, to solve the above problem in the conventional art, the multi-host service take-over system of the present invention includes a public IP address take-over module 20, a service take-over module 22, and a request processing module 26. The above modules will be described in detail below.

The public IP address take-over module 20 of the present invention is used to make one of the hosts in a standby state rapidly take over the external public IP address 10.10.1.10 of the service host 12 providing a service currently after the service host 12 fails. When multiple standby hosts exist, the standby host used for service take-over can be chosen at random. Any one or more standby hosts may detect the failure of the failed host, so the standby hosts all will try to take over the public IP address and service of the failed host. However, to avoid conflict caused by multiple standby hosts taking over the public IP address and service at the same time, mainly two techniques are widely adopted at present, namely, token ring or arbitration mechanism. The principle of the token ring is moving the token circularly among the standby hosts, and any standby host with the token has the obligation to take over the public IP address and service. The arbitration mechanism is that, no matter which standby host is adopted to take over the public IP address and service, two things must be done in advance, i.e., checking whether the standby host is “locked”, if not, perform “locking”, and then take over the public IP address and service, while if so, end the process without performing the service take-over. The above two techniques are employed to avoid conflict caused by multiple standby hosts taking over the public IP address and service simultaneously. However, it should be pointed out that the technique of the standby host taking over a service of the present invention is not limited to the above two types.

Afterward, the take-over standby host sends an instruction to require the failed service host 12 to release the public IP address used for providing a service externally. Therefore, the client computer or application that accesses via the external public IP address 10.10.1.10 originally still accesses via the address. However, the host actually having the public IP address and providing a service has changed into another host.

After the standby host 14 takes over the public IP address of the original service host 12, services such as internet-only service and static webpage website browsing service can be taken over immediately via the service take-over module 22, and then provided externally. However, for services requiring for a take-over environment, for example, network block device services and file services such as iSCSI, FTP, server message block/common internet file system (SMB/CIFS), and network file system (NFS), certain time is required for software preparation (in a few cases) and hardware preparation (in most cases). Services can only be provided via the taken-over public IP address in time and safely after the above service take-over preparation is done. Therefore, the service take-over module 22 has to prepare a software/hardware environment required for taking over the service of the failed host 12 to the standby host 14 before service take-over.

The preparation of the take-over environment of the service take-over module 22 varies with the type of the service. Some services to be taken over need the software/hardware environment required for take-over prepared in advance, which can be very time-consuming. Some services do not need to prepare the take-over environment, which can thus be taken over rapidly. Therefore, the service take-over module 22 has to determine whether an environment preparation is required for service take-over. If the preparation is not necessary, the service will be taken over immediately; otherwise, the service take-over module 22 carries out the service environment preparation for service take-over. As for whether the environment preparation for service take-over is necessary, the service take-over module 22 can determine based on the type of the service to be taken over. If the provided service is relative to storage space or file content, such as iSCSI, FTP, HTTP, NFS, SMB/CIFS, certain time is required for service environment preparation; on the contrary, for internet-only services, such as DHCP, DNS, the service take-over module 22 does not require time for service environment preparation.

Some quite time-consuming software/hardware preparations mainly regard to the hardware or waiting time, for example, the preparation for a disk, tape, etc., takes plenty of time (such as, waiting for the disk to be released by other devices, waiting for the tape to be wound to the starting position, establishing RAID, LV, snapshot), and some environment preparations may even need to wait for a timeout time. Further, some other service take-over preparations only need to make some alterations on. For example, the configuration file or the route, which is quite convenient for service take-over, as the required purpose can be achieved merely by re-starting or starting the service program of the host.

The external services of the multi-host system not only include block device access functions such as iSCSI, but also provide file access functions such as FTP, SMB/CIFS, and NFS. Further, management functions such as secure shell (SSH), Telnet, web user interface (WebUI) and meanwhile network functions such as DHCP, DNS are provided. These services can be roughly classified into two types. The first type includes services such as iSCSI, FTP, SMB/CIFS, NFS, which have to agree with the hardware resources, for example, iSCSI must be performed on a determined disk, and FTP, SMB/CIFS, NFS, etc., to be used together must be based on a certain catalog on a determined disk. The second type includes management functions such as SSH, Telnet and network functions such as DHCP, DNS, which are basically irrelevant to the hardware resources, and can be provided externally as long as the computer operates normally and the public IP address is provided properly. Therefore, these two types of services should be dealt with separately during the above double-controller failure take-over process.

As for the first type of services, not only the connection after failure must be maintained, but also the accessed space must be the same as that before the failure. Otherwise, the user access space may be changed, and thus the services cannot be provided properly. Therefore, the first type of services cannot be truly provided unless the hardware preparation is done before the failure switch.

As for the second type of services, the rapid communication after the failure must be ensured, and no apparent delay after failure must be also ensured. That is because, these services, especially the management services such as SSH, Telnet, WebUI are closely related to user experience, and any apparent delay may alleviate the quality of user experience. The failure take-over environment of the first type of services is completed by a resource preparation module 24 of the service take-over module 22. The resource preparation module 24 provides a network connection for taking over the service, and provides an access space the same as that before the service host fails. When the service to be taken over is a file service, the resource preparation module 24 provides a file storage space at the same position as that before the service host fails. When the take-over service is a block device access service, the resource preparation module prepares a block device identical to an access service block device before the service host fails.

For example, as for the storage space preparation of a disk array, the resource preparation module 24 carries out the following steps: sending an instruction to require the failed host to release the occupied disk devices, in which if the failed host is still workable, these hard disk devices are released, and otherwise, it is not necessary to release the hard disk devices as the host is already crashed down; re-initializing the public disk space of these hard disks, and meanwhile reading the assembly data of RAID, LV; assembling the hard disks respectively into RAIDs according to the assembly data of the RAID, in which the RAID is restored; dividing or initiating the RAID into different LVs according to the assembly data of the LV, in which the LV is restored. As for the iSCSI service, the devices have to be output to corresponding initiators. As for FTP, SMB/CIFS, NFS services, the devices are mounted to designated catalogs, and are assembled into different RAIDs, LVs according to the assembly data thereof till all the devices are prepared. At this point, all of the hardware resources are ready.

The environment preparation before the take-over of the address and service of the failed host carried out by the public IP address take-over module 20 and the service take-over module 22 has been illustrated above. During the aforementioned service take-over process, the service take-over module 22 determines all the services to be taken over according to the services provided by the failed host to the client via the public IP address, and correspondingly performs a rapid take-over or carries out the preparation of the take-over environment according to different service attributes. However, during the service take-over preparation, the corresponding service port is closed. At this point, if the service port is accessed via the above public IP address, an error of “Denial of Service” may occur, which causes problems in the access of the client, and the client may thus discard the service access request. Therefore, to achieve an uninterrupted and transparent service take-over during the preparation of the service take-over environment, the multi-host service take-over system of the present invention has a request processing module 26 for detecting and figuring out in time whether an environment preparation of a service to be taken over is finished. The request processing module 26 determines the preparation of the service environment or take-over service via a command call or function call, and acquires a return value indicating whether the above operation is successful or not. Or, the request processing module 26 writes a file or mark on a certain disk after the commands are made, and then detects whether the mark already exists. That is, if the mark or file exists, the environment required by the service is ready; otherwise, the environment is not ready. However, the determination method on the environment preparation of the present invention is not limited herein, and any methods that can achieve the same purpose are all applicable.

During the environment preparation of a service to be taken over, the request processing module 26 continuously detects the state of the service environment preparation to determine whether the service is taken over normally, and processes the request of accessing the corresponding service port via the taken-over external public IP address of the multi-host system. Before the service environment preparation gets ready, the request processing module 26 drops the access request data packets to the service. As the access request is discarded before being sent to the corresponding service port, the system will not return the response of “Denial of Service” to the client, and the client will send a retry request for not receiving any response.

Moreover, after the service take-over module 22 finishes the service take-over environment preparation and takes over the service, the corresponding service port is opened. Meanwhile, the request processing module 26 stops dropping the access request data packets to the service port, and begins to receive the access request data packets sent to the port, thereby achieving the purpose of providing the service externally in a normal way. As for the access to other services to be taken over and requiring for a preparation time, the operation and the function of the service can be maintained in a normal state in the above manner.

Therefore, for the client accessing the service, the service is uninterruptedly and transparently taken over. Though the time for accessing the service may be postponed temporarily, the service is uninterrupted to the end, and no data is missing, thereby ensuring the security and reliability.

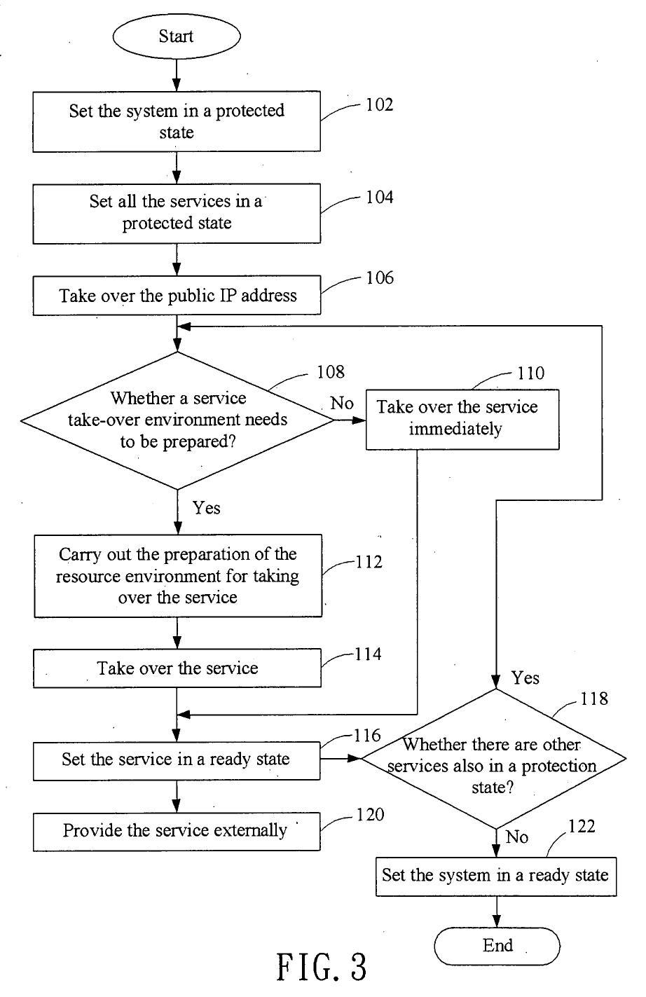

The service take-over method of the multi-host system of the present invention is illustrated below with reference to FIG. 3, which is a flow chart of the processes in the service take-over method of the multi-host system according to the present invention. The present invention is applicable to a multi-host system including a service host and at least one standby host, in which the service host and the at least one standby host mutually monitor the operating states thereof via a heartbeat mechanism. When the service host for currently providing a service fails, other standby hosts detect the state of the failed host via the heartbeat mechanism, such that one of the standby hosts takes over the public IP address and the provided service of the failed host. As some types of services require for a certain service environment in the take-over host during the process of take-over, it takes some time to prepare the service take-over environment, so all the services of the multi-host system completely or partly fail to enter a normal working state during the service take-over/switch process.

Here, the situation that all the services of the system have entered a normal working state is defined as a “Ready” state, i.e., all types of services have been taken over to the above host for taking over the public IP address and services of the failed one, and the services can be provided externally in a complete and normal way, and thus the whole multi-host system has entered a “Ready” state. On the contrary, if the system is in a “Protected” state, it indicates that the whole system has not completely entered a “Ready” state during the public IP address take-over/service take-over process or other failure switch processes. Moreover, the service “Protected” state is defined as a protected state adopted for services requiring for the preparation of a take-over software/hardware environment, i.e., the services cannot be taken over and thus cannot be provided externally in a normal way before the service environment preparation is done. As the services cannot be provided externally in a normal way, the access request data packets are dropped before the requests of the client to access the service reach the service port. The services are thus taken over till being in a “Ready” state, i.e., a state after the preparation of the service take-over environment is done, and in which the services can be externally provided in a normal way. At this point, the drop of the access request data packets of the corresponding service port is stopped, and the access request data packets sent to the port are received, so as to achieve the purpose of externally providing the service in a normal way.

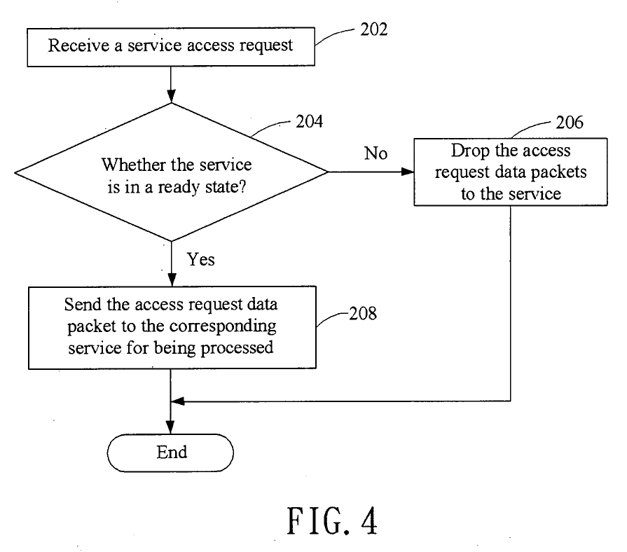

Now, referring to FIG. 3, first, the state of the standby host system is set in a protected state (Step 102), a mark is recorded, and meanwhile all the services of the standby host system are set in a protected state (Step 104). As all the services are in a “Protected” state, the result of the access request processing is achieved by simply dropping all the service requests on default. The above state-setting step is an important part of the present invention, and the request processing step of the system and service in a “Protected” state is illustrated in detail below with reference to FIG. 4.

FIG. 4 is a schematic flow chart of the access request processing of the service in a “Protected” state, in which when the client accesses the standby host system, the flow of processing the service access request of the client is shown in the figure. An access request to a certain service sent by the client is received by the system in a “Protected” state (Step 202), and it is determined whether the service is in a “Ready” state (Step 204). If the service is not in a “Ready” state, i.e., the service is in a “Protected” state currently, the access request data packets to the service are thus dropped (Step 206); otherwise, the access request data packets are sent to the corresponding service for being processed (Step 208).

The drop of the access request data packets to the service in a “Protected” state can be achieved in various ways, and for Unix/Linux platform, the simplest way is using iptables/netfilter. For example, the following instruction can be adopted to drop all the requests for “iSCSI” service:

#iptables -A INPUT -p tcp—dport 3260-j DROP, wherein 3260 is a service port of iSCSI.

As for a service in a non-“Protected” state, i.e., the service is in a “Ready” state, the drop operation on the access request to the service is canceled, i.e., eliminating the protection to the service and requiring the service to process the access request. For example, the instruction for canceling the drop of the access request is:

#iptables -D INPUT -p tcp—dport 3260-j DROP

#iptables -A INPUT -p tcp—dport 3260-j ACCEPT

The above two processes remove the “Protected” state of the service, such that the system can receive and process the service requests sent to the “iSCSI” which are discarded in the above step.

It should be pointed out that, a general example of implementing the above operations is given here, instead of limiting the protecting range of the present invention, and any conventional art that can achieve the operations mentioned above is applicable to the present invention.

After the system and the service are set in a “Protected” state, the public IP address of the failed host for providing a service externally is taken over (Step 106). The take-over of a public IP address is a conventional art, which can refer to, for example, codes for achieving public IP take-over in a Linux virtual server (LVS). Next, each service can be taken over. The system provides multiple external services, and those that do not require for any software/hardware preparation or require for a short preparation can be provided by the system at once. Thus, it is determined whether the service to be taken over needs the preparation of the service take-over environment (Step 108), and if not, the service is taken over immediately (Step 110). For example, services providing management functions and network functions are basically irrelevant to the hardware resources, and thus can be provided externally after the public IP address is provided in a normal way.

Whether a service take-over environment has to be prepared in Step 108 can be determined according to the type of the service to be taken over. If the provided service is relative to storage space or file content, such as iSCSI, FTP, HTTP, NFS, SMB/CIFS, certain time is required for service environment preparation; on the contrary, for internet-only services, such as DHCP, DNS, no time is required for service environment preparation.

In view of the above, some services agreeing with the hardware resources, such as iSCSI, FTP, cannot be provided immediately due to the preparation of the service take-over environment, and thus the process proceeds to Step 112 of carrying out the preparation of the resource environment for performing service take-over (Step 112). The processes of the environment preparation will be illustrated in detail below.

When carrying out the preparation of the service take-over environment, the environment preparation varies with the type of the service. Some quite time-consuming software/hardware preparations mainly regard to the hardware or waiting time, and some may even need to wait for a timeout time. Further, some other service take-over preparations only need to make some alterations on. For example, the configuration file or the route, which is quite convenient for service take-over, as the required purpose can be achieved merely by re-starting or starting the service program of the host.

As for the services that must agree with the hardware resources, not only the network connection for the service take-over after the failure must be maintained, but also the accessed space must be the same as that of the failed host before the failure. Otherwise, the user access space may be changed, and thus the services cannot be provided properly. Therefore, such type of services cannot be truly provided unless the hardware preparation is done before the failure switch. When the service to be taken over and agreeing with the hardware resources is a file service, a file storage space at the same position as that before the service host fails must be provided. When the service to be taken over is a block device access service, a block device identical to an access service block device before the service host fails must be prepared.

The service is taken over after the preparation of the resource environment for service take-over is done (Step 114). After that, the service enters a “Ready” state (Step 116), and is provided externally in a normal way (Step 120). Though the service which is time-consuming during the take-over requires for a long time for the resource preparation, all the requests from the system to access the service via the public IP address, i.e., the public IP data packets, are dropped under a double-“Protected” state of the system and service, so the message of “Denial of Service” may not occur, and the client may continuously retry the service. Referring to the schematic flow chart of the request processing of the service in a “Protected” state of FIG. 4, under such a circumstance, any service can be taken over properly regardless of the necessity of a preparation.

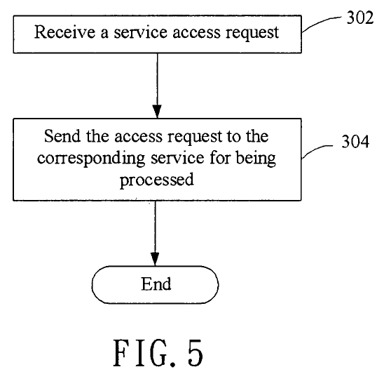

After a service enters a “Ready” state (Step 116), it is determined whether there are other services also in a “Protected” state (Step 118), and if not, the whole system is set in a “Ready” state (Step 122); otherwise, the process proceeds to Step 108 to carry out Steps 108 to 122 for other services in a “Protected” state to be taken over. The above steps are repeated till all the services are taken over, and the services are all in a “Ready” state, i.e., the whole system is in a “Ready” state. At this point, the access request to the service will be processed according to a schematic flow chart of the request processing of the service in a “Ready” state of FIG. 5.

As shown in FIG. 5, the host system receives the access request to the service port (Step 302), and directly sends the request to the corresponding service for being processed (Step 304), which is a processing flow in a normal state, and the system is in such state in most of the time. At this point, no request data packet is dropped. Once the whole system is set in a “Ready” state, the above public IP take-over step, service take-over step, and the step of dropping the access request data packets are abandoned, and the take-over host processes automatically until the next failure switch, in which these steps interact to fulfill a safe failure switch.

Seen from the above, the present invention not only ensures that the services of rapid switch property can be provided at once, but also ensures an uninterrupted connection between the client and the server when the services fail to be provided rapidly. Moreover, the present invention not only ensures that the services that fail to be provided rapidly can be provided in time after being ready, but also ensures the reliability of various services which are clustered on a high available host system. When the service failure take-over is performed under the above circumstances, the user can truly enjoy a multi-service system of uninterrupted and transparent switch as well as a preferred user experience.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A service take-over system of multi-host system, applicable to a multi-host system comprising a service host and at least one standby host, the service host providing a service externally via an external public IP address, the standby host being in a standby state, and the service host and the at least one standby host mutually monitoring operating states thereof via a heartbeat mechanism, the service take-over system comprising:
a public IP address take-over module, for determining the operating state of the service host though the heartbeat mechanism, and sending a resource release request to inform the service host to release the occupied external public IP address and the service when the service host fails, so as to take over the external public IP address to one of the standby hosts;
a service take-over module, for preparing a service environment required for taking over the service of the service host to the standby host, and taking over the service; and
a request processing module, for detecting preparation state of the service environment of the service take-over module, and dropping access request data packets via the external public IP address to the service before the service environment gets ready.

2. The service take-over system of multi-host system as claimed in claim 1, wherein the request processing module further comprises a resource preparation module, for generating a service environment required by a service take-over agreed with a hardware resource.

3. The service take-over system of multi-host system as claimed in claim 2, wherein the resource preparation module provides a network connection for taking over the service, and provides an access space identical to that before the service host fails.

4. The service take-over system of multi-host system as claimed in claim 3, wherein when the service to be taken over is a file service, the resource preparation module provides a file storage space at a same position as that before the service host fails.

5. The service take-over system of multi-host system as claimed in claim 3, wherein when the service to be taken over is a block device access service, the resource preparation module prepares a block device identical to an access service block device before the service host fails.

6. The service take-over system of multi-host system as claimed in claim 1, wherein the service take-over module determines whether an environment preparation is needed to take over the service; if not, the service is taken over at once; otherwise, the service take-over module prepares the service environment required for taking over the service.

7. A service take-over method of multi-host system, applicable to a multi-host system comprising a service host and at least one standby host, the service host and the at least one standby host mutually monitoring operating states thereof via a heartbeat mechanism, the method comprising:
determining the operating state of the service host via the heartbeat mechanism, and sending a resource release request to inform the service host to release an occupied external public IP address and a service when the service host fails;
taking over the external public IP address released by the service host to one of the standby hosts;
preparing a service environment required for taking over the service of the service host to the standby host;
detecting preparation state of the service environment, and dropping access request data packets via the external public IP address to the service before the service environment gets ready; and
taking over the service after the service environment is ready, and receiving the access request data packets to the service, so as to provide the service externally.

8. The service take-over method of multi-host system as claimed in claim 7, further comprising a step of generating the service environment required by a service take-over agreed with a hardware resource.

9. The service take-over method of multi-host system as claimed in claim 8, wherein the step of preparing the service environment comprises:
providing a network connection for taking over the service; and
providing an access space identical to that of the service host before the service host fails.

10. The service take-over method of multi-host system as claimed in claim 9, wherein when the service to be taken over is a file service, a file storage space at a same position as that of the service host before the service host fails is provided.

11. The service take-over method of multi-host system as claimed in claim 9, wherein when the service to be taken over is a block device access service, a block device identical to an access service block device before the service host fails is prepared.

12. The service take-over method of multi-host system as claimed in claim 7, wherein before the step of preparing the service environment, the method further comprises a step of determining whether an environment preparation is needed to take over the service; if not, the service is taken over at once; otherwise, the service environment required for taking over the service is prepared.
